(19) United States
(12) Patent Application Publication
(10) Pub. No.: US 2011/0169495 A1
(43) Pub. Date: Jul. 14, 2011

(54) MONITORING MODULE INCLUDING E-FIELD-INDUCED ESD-SENSITIVE PATTERN AND PHOTOMASK INCLUDING THE MODULE

(76) Inventors: Su-Young Lee, Seongnam-si (KR); In-Kyun Shin, Yongin-si (KR); Yun-Song Jeong, Osan-si (KR)

(21) Appl. No.: 12/910,223

(22) Filed: Oct. 22, 2010

(30) Foreign Application Priority Data
Jan. 14, 2010 (KR) 10-2010-0003630

(51) Int. Cl. G01N 27/60; G03F 1/00

(52) U.S. Cl. 324/452; 430/5

(57) ABSTRACT

Provided are a monitoring module of an electrostatic discharge (ESD)-sensitive photomask, in which when an external electric field (E-field) exists, monitoring patterns are formed in the same direction as or a vertical direction to the external E-field, and a photomask including the module. The monitoring module includes a plurality of monitoring patterns, which are electrically isolated from one another and arranged at right angles to one another. At least one first monitoring pattern of the plurality of monitoring patterns is arranged in the same direction as an E-field existing outside the photomask. At least one second monitoring pattern of the plurality of monitoring patterns is arranged at substantially right angles to the first monitoring pattern in consideration of a direction in which charges move due to rotation of the photomask.

### CROSS-REFERENCE TO RELATED APPLICATION

This application claims priority under 35 U.S.C. §119 to Korean Patent Application No. 10-2010-0003630 filed on Jan. 14, 2010, the disclosure of which is hereby incorporated by reference in their entirety.

### BACKGROUND

1. Field

Embodiments of the inventive concept relate to a monitoring module including an external electric field (E-field)-induced electrostatic-discharge (ESD)-sensitive pattern and a photomask including the module.

2. Description of Related Art

In recent years, with an increase in the integration density of semiconductor devices and a reduction in the design rule of the semiconductor devices, patterns of the semiconductor devices have also been shrinking.

### SUMMARY

Embodiments of the inventive concept provide an electrostatic-discharge (ESD) monitoring module capable of monitoring ESD amplified due to an external electric field (E-field).

Also, embodiments of the inventive concept provide a monitoring photomask capable of monitoring ESD amplified due to an external E-field.

The technical objectives of the inventive disclosure are not limited to the above disclosure; other objectives may become apparent to those of ordinary skill in the art based on the following descriptions.

In accordance with an aspect of the inventive concept, an ESD monitoring module of a photomask includes a plurality of monitoring patterns electrically isolated from one another. The plurality of monitoring patterns are arranged at right angles to one another.

Each of the monitoring patterns may have a bar shape with a length greater than a width.

At least one first monitoring pattern of the plurality of monitoring patterns may be arranged in the same direction as an E-field existing outside the photomask.

At least one second monitoring pattern of the plurality of monitoring patterns may be arranged at substantially right angles to the first monitoring pattern in consideration of a direction in which charges move due to rotation of the photomask.

When a monitoring pattern with a smaller width and a greater length and a monitoring pattern with a greater width and a smaller length, out of the plurality of monitoring patterns, have the same area, the probability of ESD may be higher in the monitoring pattern with the smaller width and the greater length than in the monitoring pattern with the greater width and the smaller length.

When the plurality of monitoring patterns include monitoring patterns having a smaller gap therebetween and monitoring patterns having a greater gap therebetween, the probability of ESD may be higher in the monitoring patterns having the smaller gap therebetween than in the monitoring patterns having the greater gap therebetween.

Each of the plurality of monitoring patterns may be split in parallel into a plurality of sub-patterns in a widthwise direction from the same layout direction.

Adjacent monitoring patterns disposed in the widthwise direction, out of the plurality of monitoring patterns, may be connected to each other by a bridge in the widthwise direction.

The ESD monitoring module may be formed in a monitoring-only photomask.

The ESD monitoring module may be formed in an additional space of a photomask configured to perform an exposure process.

The additional space may be a blind area.

The monitoring patterns may be formed by patterning a light blocking layer formed of chromium (Cr) on a transparent substrate.

In accordance with another aspect of the inventive concept, an ESD monitoring module of a photomask includes first monitoring patterns and second monitoring patterns, which are electrically connected to one another and combine into one line-type pattern. The line-type pattern is bent such that the first monitoring patterns are designed in the same direction as an E-field existing outside the photomask and the second monitoring patterns are designed at right angles to the E-field.

The line-type pattern may have a spiral structure in which the length of the first monitoring patterns or second monitoring patterns is regularly reduced inward.

The line-type pattern may have a zigzag structure in which the first monitoring patterns and the second monitoring patterns are repetitively arranged.

In accordance with still another aspect of the inventive concept, a monitoring photomask includes: a transparent substrate through which light is transmitted; and a light blocking pattern disposed on the transparent substrate, the light blocking pattern through which light is not transmitted. The light blocking pattern includes: a monitoring module on which a plurality of monitoring patterns are arranged; and a blind area disposed adjacent to the monitoring module. The monitoring patterns are formed to have a greater length than a width thereof and used to monitor both ESD sensitivity and pattern damage caused by friction when the transparent substrate is rotated during a cleaning process.

The plurality of monitoring patterns are electrically isolated from one another. At least one first monitoring pattern of the plurality of monitoring patterns may be arranged in the same direction as an E-field existing outside the monitoring photomask. At least one second monitoring pattern of the plurality of monitoring patterns may be arranged at right angles to the E-field.

Each of the monitoring patterns may have a simple bar-type structure. The bar-type structure may be arranged at right angles to the blind area so that a potential difference can be amplified in a gap between the bar-type monitoring pattern and the blind area or in a gap between adjacent bar-type monitoring patterns.

The monitoring patterns may be electrically connected to one another and combine into one pattern, which is arranged as a spiral type in the same direction as or at right angles to an E-field existing outside the monitoring photomask. A potential difference may be amplified in a gap between the spiral light blocking pattern and the light blocking pattern of the blind area or in a gap between adjacent spiral light blocking patterns.

The monitoring patterns may be designed to a width of about 150 nm to about 400 nm to cause pattern damage due to friction during a cleaning process. The monitoring patterns constitute unit monitoring modules, which correspond to a plurality of cells, respectively, and a distance between the unit monitoring modules may be about 5 mm or more.

Particulars of other embodiments are included in the detailed description and drawings.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1 is a perspective view of a photomask including a plurality of light blocking patterns formed on a transparent substrate according to embodiments of the inventive concept;

FIG. 2 is a plan view of a monitoring module including a monitoring pattern according to embodiments of the inventive concept;

FIG. 3 is a plan view of a monitoring module formed on the entire substrate in a monitoring-only photomask according to embodiments of the inventive concept;

FIG. 4 is a plan view of a photomask applicable to an actual exposure process, in which monitoring modules are additionally formed in a blind area, according to embodiments of the inventive concept;

FIG. 5 is a plan view showing the probability of ESD relative to the length of a monitoring pattern with the application of an external E-field, according to embodiments of the inventive concept.

FIG. 6 is a plan view showing the probability of ESD relative to the position of each monitoring pattern with the application of an external E-field, according to embodiments of the inventive concept;

FIG. 7 is a is a perspective view showing an aerosol local cleaning process using an eco-snow system according to embodiments of the inventive concept;

FIG. 8 is a plan view of a monitoring module in which a monitoring pattern most sensitive to ESD is arranged as a bar type with application of an external E-field, according to embodiments of the inventive concept;

FIG. 9 is a plan view of a monitoring module in which bar-shaped monitoring patterns, which are electrically isolated from one another, are arranged in an “L” form with the application of an external E-field, according to embodiments of the inventive concept;

FIG. 10 is a plan view of a monitoring module in which bar-shaped monitoring patterns, which are electrically isolated from one another, are arranged in an “L” form and further split in parallel;

FIG. 11 is a plan view of a monitoring module in which adjacent monitoring patterns are connected to each other by a bridge, according to embodiments of the inventive concept;

FIG. 12 is a plan view of a monitoring module in which one monitoring pattern is arranged in a spiral form, according to embodiments of the inventive concept;

FIG. 13 is a plan view of a monitoring module in which one monitoring pattern is arranged in a zigzag form, according to embodiments of the inventive concept; and

FIG. 14 is a plan view of an all-in-one ESD monitoring photomask capable of monitoring occurrence of pattern failures and ESD due to friction during a cleaning process according to embodiments of the inventive concept.

### DETAILED DESCRIPTION OF THE EMBODIMENTS

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concept. As used herein, the singular fowls “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A semiconductor fabrication process may include a plurality of photolithography processes of aiming various circuit devices on a semiconductor substrate. Each of the photolithography processes may include transferring a pattern formed on a photomask onto the semiconductor substrate using photoresist.

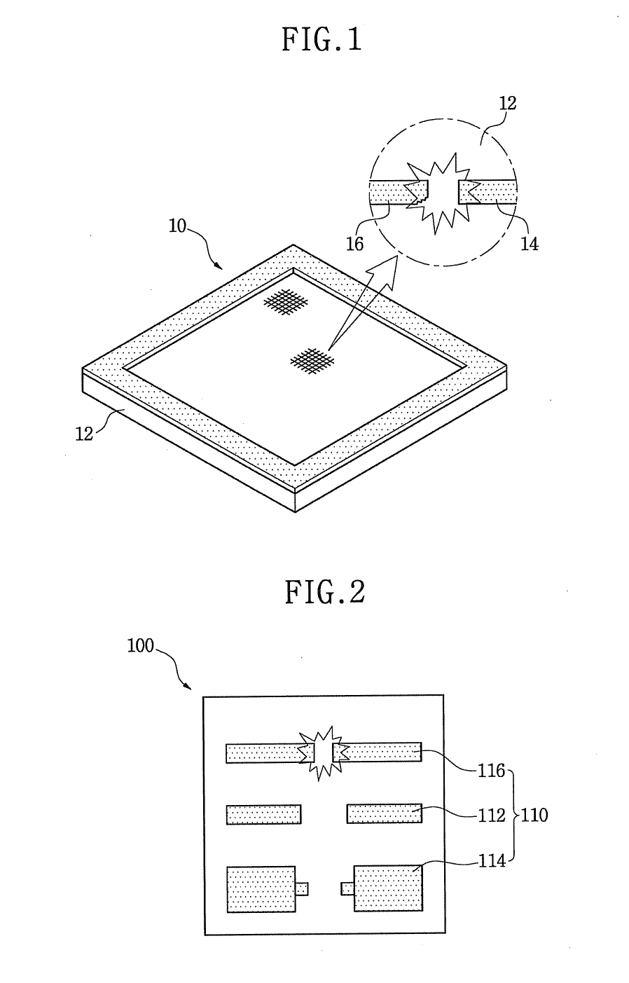

FIG. 1 is a perspective view of a photomask according to embodiments of the inventive concept.

Referring to FIG. 1, a photomask 10 may include a transparent substrate 12 and light blocking patterns 14. The transparent substrate 12 may be formed of an insulating material, such as quartz. The light blocking patterns 14 may be formed of a conductive material, such as chromium (Cr).

A process of manufacturing the photomask 10 or a process using the photomask 10 may include a plurality of cleaning processes and/or a plurality of transferring processes. The photomask 10 may be charged with electricity due to contact or friction with another object or external factors during repeated cleaning or transferring processes. Due to the electrical charge, static electricity may occur in the photomask 10.

Referring back to FIG. 1, a potential difference may occur between the light blocking patterns 14 electrically isolated from one another. The potential difference may be several tens of kV or higher. When the potential difference exceeds a threshold voltage, electrostatic discharge (ESD) may occur between the light blocking patterns 14. The light blocking patterns 14 may be broken during the ESD. When the broken light blocking patterns 16 are transferred onto a semiconductor device, pattern failures may be caused.

Since it is not easy to previously find risk factors, such as ESD, a monitoring module may be required. Also, when weak ESD occurs during a process of manufacturing the photomask 10, it is difficult to track and compensate for the ESD so that the monitoring module can be required. Furthermore, even after the manufacturing process is finished, ESD may continuously occur during repeated use of the photomask 10. For example, it is very difficult to find risk factors during photomask manufacturing processes of at least 50 steps or processes using the photomasks. Even if some risk factors are found, it is also very complicated to resolve the risk factors.

FIG. 2 is a plan view of a monitoring module according to embodiments of the inventive concept.

To increase yield, a monitoring method for finding the cause of pattern failures beforehand may be required. For instance, risky elements, such as ESD, may be found beforehand using a monitoring-only photomask. Alternatively, monitoring patterns may be additionally formed in an ordinary photomask. Referring to FIG. 2, a monitoring module 100 capable of increasing ESD sensitivity may be required so that all parameters of ESD that cause a breakdown may be considered.

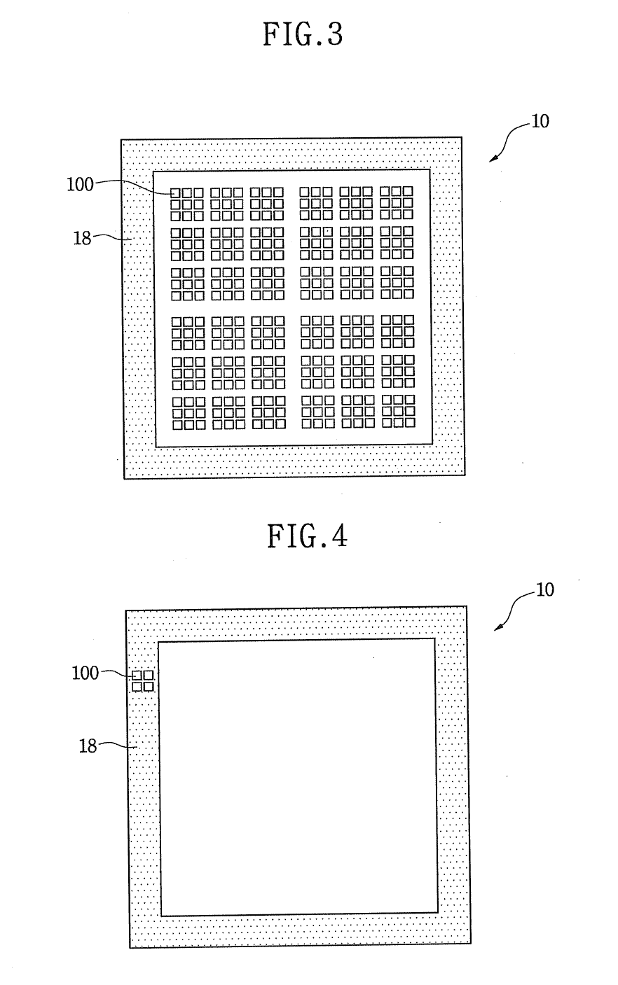

FIG. 3 is a plan view of a monitoring module formed on the entire substrate in a monitoring-only photomask according to embodiments of the inventive concept, and FIG. 4 is a plan view of a photomask applicable to an actual process, in which monitoring modules are additionally formed in a blind area, according to embodiments of the inventive concept.

Referring to FIG. 3, a monitoring module 100 may be a monitoring-only photomask 10. Referring to FIG. 4, a monitoring module 100 may be additionally formed on one side of a photomask 10. For example, referring to FIG. 4, the monitoring module 100 may be disposed in a blind area 18 or scribe area of the photomask 10. Thus, the photomask 10 may be a monitoring-only photomask or an actual photomask used for an exposure process, on which additional monitoring patterns are further formed on the blind area 18 so that the exposure process and a monitoring process can be performed at the same time.

Referring to FIG. 3, when the photomask 10 is manufactured as a monitoring-only photomask, the photomask 10 may include the monitoring module 100 formed in the center thereof and the blind area 18 formed in an edge thereof. The monitoring module 100 may form a plurality of cells.

Referring back to FIG. 2, a monitoring pattern 110 may include a plurality of sub-monitoring patterns 112, 114, and 116, which are electrically isolated from one another. In this case, as the sizes of the sub-monitoring patterns 112, 114, and 116 increase, the monitoring pattern 110 may be charged with charges more easily and the probability of ESD may be increased. Thus, as the sizes of the sub-monitoring patterns 112, 114, and 116 increase, the sub-monitoring patterns 112, 114, and 116 may become more sensitive to ESD. For example, the sub-monitoring pattern 114 with a greater size may become more sensitive to ESD than the sub-monitoring pattern 112 with a smaller size.

Also, as a gap between the monitoring patterns 110 decreases, a breakdown voltage may decrease, so that the probability of ESD can also increase. Thus, as the gap between the monitoring patterns 110 decreases, the monitoring patterns 110 may become more sensitive to ESD. For example, the sub-monitoring patterns 116 between which a gap is smaller may become more sensitive to ESD than the sub-monitoring patterns 112 between which a gap is greater.

The above-described example may be applied to an ideal case where an external electric field (E-field) or magnetic field (M-field) is not applied. However, in an actual case where the external E-field or M-field is applied, ESD sensitivity may be varied according to the position or shape of the monitoring patterns 110. That is, the probability of ESD may be varied several tens to several hundreds of times according to the diversity of pattern shapes or the environment. Thus, a monitoring module capable of monitoring ESD induced by an E-field may be required.

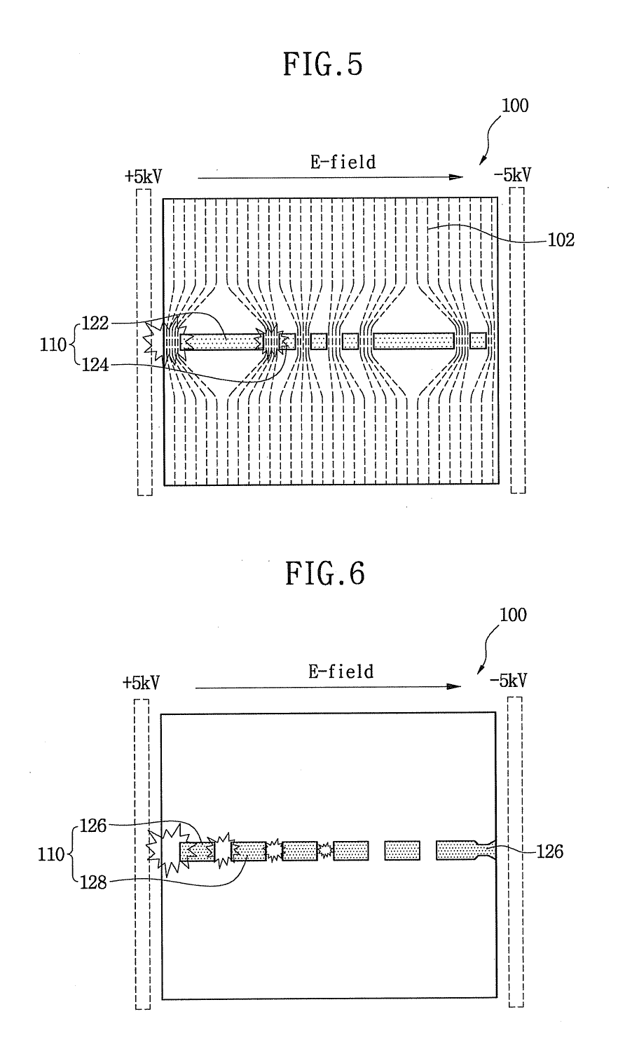

FIG. 5 is a plan view showing the probability of ESD relative to the length of a monitoring pattern with the application of an external E-field, according to embodiments of the inventive concept. In FIG. 5, it is assumed that there is a potential difference of about 10 kV adjacent to the monitoring module 100, and a direction of the external E-field is aligned with a lengthwise direction of each monitoring pattern.

Referring to FIG. 5, when an external E-field is applied, a plurality of equipotential lines 102 may be formed adjacent to a monitoring module 100 of a photomask. In this case, although a gap between monitoring patterns 110 is constant, the respective monitoring patterns 110 may have different lengths so that the distribution of the equipotential lines 102 passing through each gap may differ. Comparing a short pattern 122 with a long pattern 124, the equipotential lines 102 passing between the long patterns 124 are distributed at a higher density than the equipotential lines 102 passing between the short patterns 122, and a potential difference between the long patterns 124 may be amplified more than a potential difference between the short patterns 122. Thus, even if the gap between the short patterns 122 is equal to the gap between the long patterns 124, the equipotential lines 102 passing between the long patterns 124 may have a greater potential difference therebetween and become more sensitive to ESD than the equipotential lines 102 passing between the short patterns 122.

Therefore, the probability of ESD relative to the amplification of a potential difference may be previously understood by controlling the length of the monitoring patterns 110 so that risk factors can be monitored beforehand.

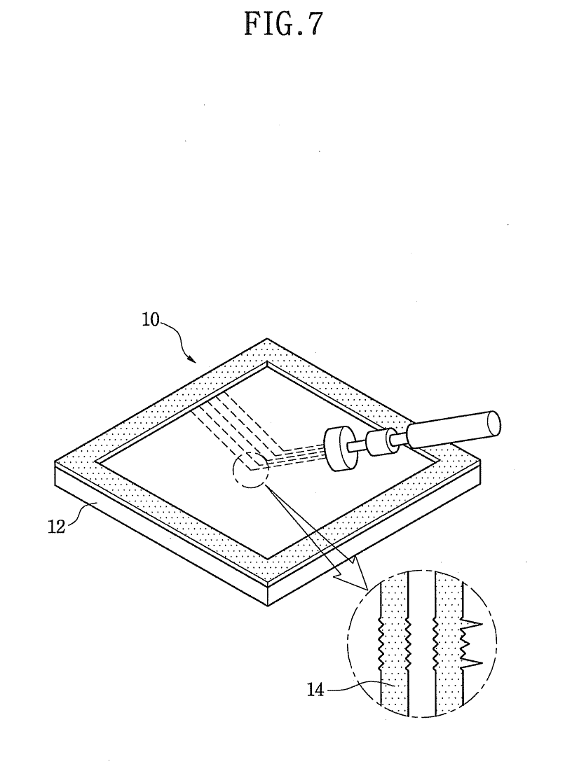

FIG. 6 is a plan view showing the probability of ESD relative to the position of monitoring patterns with the application of an external E-field, according to embodiments of the inventive concept.

Referring to FIG. 6, when an external E-field or M-field is applied, a potential difference may vary with the position of the monitoring patterns. For example, since a potential difference is amplified in an edge of the monitoring module 100 of the photomask more than in the center thereof, a peripheral monitoring pattern 126 may become more sensitive to ESD than a central monitoring pattern 128. Thus, even if the respective monitoring patterns 110 have the same length and the gap between the monitoring patterns 110 is constant, when an external E-field is applied, as the monitoring patterns 110 become closer to a blind area, the likelihood of a breakdown may be higher. Even if a breakdown does not happen, a bridge effect may occur, so the peripheral monitoring pattern 126 adjacent to the blind area may be connected to a light blocking pattern of the blind area.

As described above, a monitoring photomask capable of increasing ESD sensitivity in consideration of both internal conditions of a photomask and external conditions, such as an external E-field, may be required.

Among various parameters, an E-field or M-field applied to the vicinity of the photomask 10 may most significantly affect the probability of ESD. When ESD is induced by an E-field or M-field adjacent to the photomask 10, an ESD-sensitive monitoring pattern 110 may be formed. The ESD-sensitive monitoring pattern 110 may be formed as a line type or bar type. The ESD-sensitive monitoring pattern 110 may have various ESD-sensitivities according to a pattern length, a pattern position, a gap between patterns, or a pattern shape.

Meanwhile, the most vulnerable process for manufacturing or employing the photomask 10 may be a cleaning process. This is because the photomask 10 may rotate and various ESD-induced cleaning agents may be used during the cleaning process. Furthermore, in addition to the process of monitoring ESD in a photomask manufacturing process or a process using the photomask, other monitoring processes for monitoring an assist bar or a personal computer (PC) may be performed.

FIG. 7 is a perspective view showing an aerosol local cleaning process using an eco-snow system according to embodiments of the inventive concept.

Referring to FIG. 7, for example, when a cleaning process is performed using an eco-snow system, dry ice may be sprayed. A light blocking pattern 14 may be damaged due to friction with solid dry ice. Therefore, pattern failures, such as a cut in the light blocking pattern 14 or pattern collapse, due to friction should be monitored. Also, in the case of an ultrasonic cleaning process, the extent of ESD should be monitored according to the intensity of ultrasonic waves or the concentration of a cleaning agent.

Accordingly, several photomasks suited to respective monitoring purposes may be required. Since patterns are mostly sensitive to ESD during at least a cleaning process, embodiments of the inventive concept may provide an all-in-one monitoring photomask applicable to a process of monitoring pattern failures during a cleaning process.

That is, the probability of ESD may be increased due to ultrasonic waves or cleaning agents during a cleaning process. Furthermore, when the photomask is transferred or rotated during the cleaning process, the probability of ESD may be further increased due to the transport of charges. Hereinafter, monitoring modules capable of monitoring the occurrence of ESD in consideration of all directions in which charges move when an external E-field is applied to a photomask and the photomask is rotated during a cleaning process will be described.

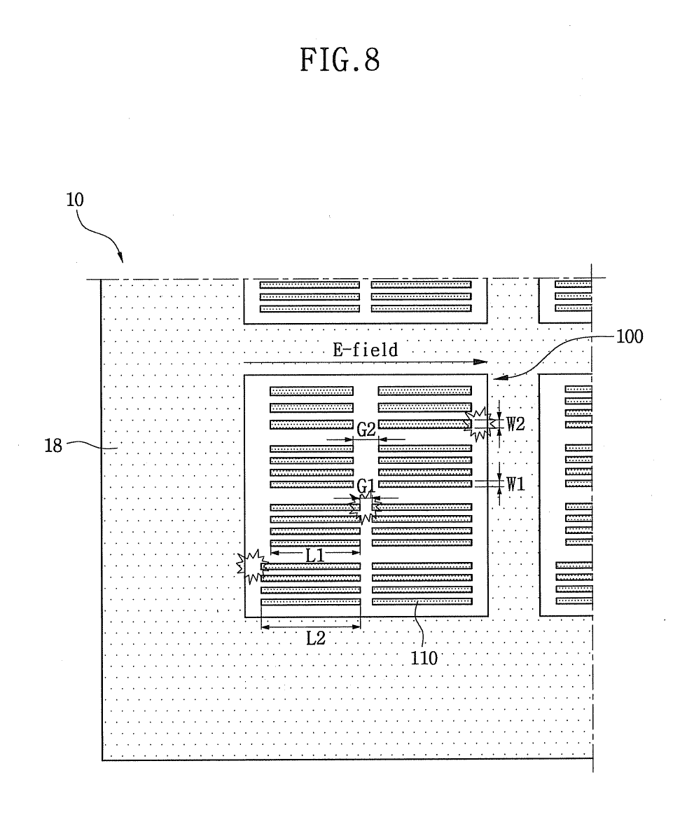

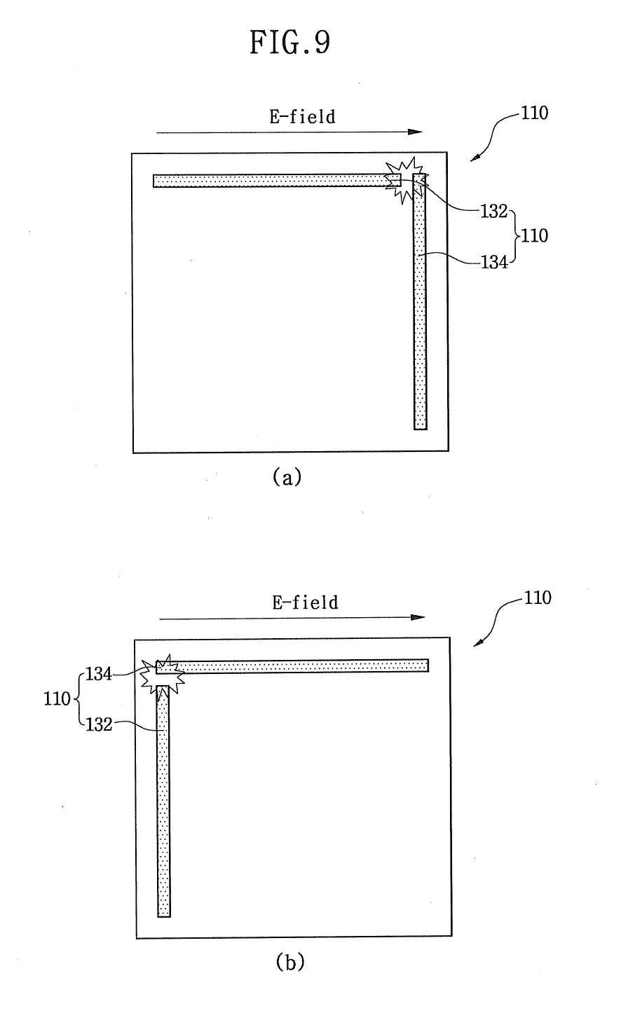

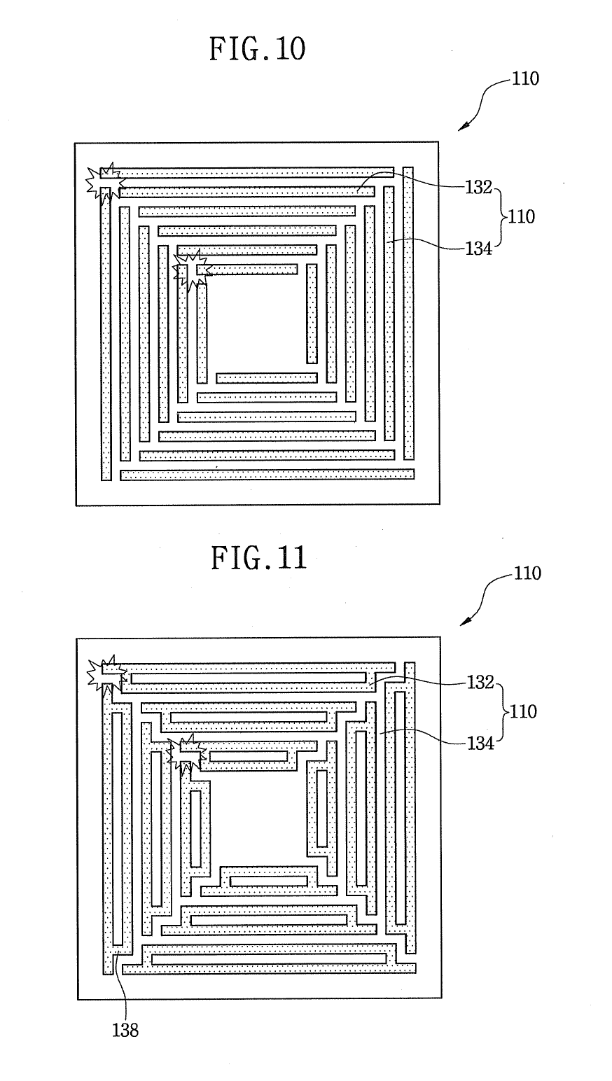

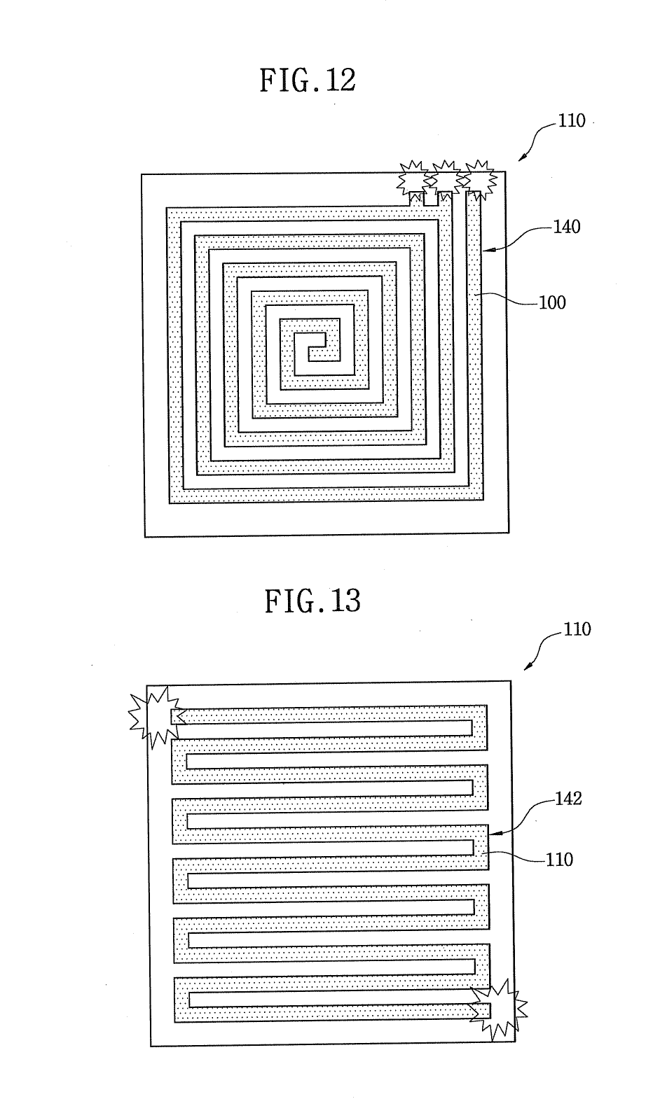

FIG. 8 is a plan view of a monitoring module in which a monitoring pattern most sensitive to ESD is arranged as a bar type with application of an external E-field, according to embodiments of the inventive concept, FIG. 9 is a plan view of a monitoring module in which bar-shaped monitoring patterns, which are electrically isolated from one another, are arranged in an “L” form with the application of an external E-field, according to embodiments of the inventive concept, FIG. 10 is a plan view of a monitoring module in which bar-shaped monitoring patterns, which are electrically isolated from one another, are arranged in an “L” form and further split in parallel, FIG. 11 is a plan view of a monitoring module in which adjacent monitoring patterns are connected to each other by a bridge, FIG. 12 is a plan view of a monitoring module in which one monitoring pattern is arranged in a spiral form, and FIG. 13 is a plan view of a monitoring module in which one monitoring pattern is arranged in a zigzag form.

Referring to FIG. 8, when an E-field exists outside a photomask, there must be a point in time when the direction of the E-field may be aligned with a lengthwise direction of the monitoring patterns 110 somehow or other during a process of rotating or transferring the photomask. In this case, when the E-field is aligned with the lengthwise direction of the monitoring patterns 110, as the length of the monitoring patterns 110 is increased from L1 to L2, a potential difference may be amplified in the vicinity of a gap between the monitoring patterns 110. Thus, as the length of the monitoring patterns 110 is increased from L1 to L2, the monitoring patterns 110 may be more sensitive to ESD with induction of the E-field.

Also, as the gap between the monitoring patterns 110 is increased from G1 to G2, a potential difference may be amplified in the vicinity of the gap between the monitoring patterns 110, so that the probability of ESD with application of the E-field may be increased. Thus, as the gap between the monitoring patterns 110 is increased from G1 to G2, the monitoring patterns 110 may be more sensitive to ESD with induction of the E-field.

Furthermore, as the width of the monitoring patterns 110 is increased from W1 to W2, a potential difference may be amplified in the vicinity of the gap between the monitoring patterns 110 so that the monitoring patterns 110 may be more sensitive to ESD with induction of an E-field. However, since the width of the monitoring patterns 110 is restricted by a design rule, there is a specific limit for increasing the width of the monitoring patterns 110. Meanwhile, when the monitoring patterns 110 has the same absolute area, as the width of the monitoring patterns 110 decreases and the length of the monitoring patterns 110 increases, the probability of ESD may further increase.

As described above, the most vulnerable process for manufacturing or employing the photomask may be a cleaning process. Since the photomask is rotated during the cleaning process, all directions in which charges move due to the rotation of the photomask should be considered. In consideration of all the directions in which charges move during the rotation of the photomask, the monitoring pattern 110 that is most sensitive to ESD may be arranged in an “L” form as shown in FIG. 9.

Specifically, among a plurality of isolated patterns electrically isolated from one another, one isolated pattern 132 may extend in a widthwise direction of the monitoring pattern 110, and another isolated pattern 134 may extend in a lengthwise direction thereof. In this case, as shown in case (a) of FIG. 9 the probability that a lengthwise direction of the isolated pattern 132 will be aligned with the direction of an E-field may be increased. Also, as can be seen from case (b), even if the photomask is rotated, the probability that the lengthwise direction of the isolated pattern 134 will be aligned with the direction of the external E-field may be increased. Therefore, the probability that a potential difference will be amplified in the vicinity of a gap between the isolated patterns 132 and 134 arranged at right angles to each other may be doubled, so that the monitoring pattern 110 can be more sensitive to ESD.

Referring again to FIG. 8, even if monitoring patterns 110 are formed as a simple bar type, the monitoring patterns 110 may be sensitive to ESD in the same way when the monitoring patterns 110 are arranged in an “L” form. For example, when the bar-type monitoring patterns 110 are arranged adjacent to a blind area 18 at right angles to light blocking patterns of the blind area 18, ESD may be induced in gaps between the light blocking patterns of the blind area 18 and the monitoring patterns 110.

Referring to FIG. 10, a plurality of bar-type monitoring patterns, which are electrically isolated from one another, may be arranged in an “L” form, and each of the bar-type patterns may be split in parallel. That is, each of the monitoring patterns, which are electrically isolated from one another and arranged at right angles to one another, may be split in parallel into a plurality of sub-patterns in a widthwise direction from the same layout direction.

It goes without saying that patterns should be formed to a great area to ensure large charges required for ESD. In order to increase the area of the monitoring patterns, various methods may be considered. First, the monitoring patterns may be formed to a great length and width to increase the area thereof. However, as described above, the width of the monitoring patterns may be restricted by design rules.

Referring to FIG. 11, the monitoring patterns 110, which are isolated from one another, may be formed to a small width and a long length and connected to each other in a widthwise direction. Specifically, a pair of adjacent monitoring patterns 110, which are electrically isolated from each other, may be connected to each other by a bridge 138 to increase the entire area of the monitoring patterns 110.

Referring to FIG. 12, although the monitoring patterns 110 may be formed to a great length and a small width, all the monitoring patterns 110 may combine into one monitoring pattern to maximize the entire area. The monitoring patterns 110, which are electrically isolated from one another and formed at right angles to one another, may combine into one spiral monitoring pattern. For example, the spiral monitoring pattern may be a square monitoring pattern 140 whose length is regularly reduced inward. Therefore, the spiral monitoring pattern may be most sensitive to ESD with application of an external E-field because the area of the spiral monitoring pattern 110 may be maximized in consideration of all external conditions of an E-field induced due to rotation of a photomask.

Referring to FIG. 13, monitoring patterns 110 may be electrically connected to one another and combine into one zigzag pattern 142, which may be bent in the same direction as or at right angles to an external E-field. Thus, the monitoring patterns 110 may be repetitively designed in a widthwise or lengthwise direction, thereby maximizing the entire area of the monitoring patterns 110.

Therefore, to optimize the design rule of a light blocking pattern of a photomask according to embodiments of the inventive concept, the probability of ESD may be extracted based on various factors of monitoring patterns, such as the length, width, or area of the monitoring patterns or a gap between the monitoring patterns.

For example, as a gap between monitoring patterns 110 decreases, the monitoring patterns 110 may be more sensitive to ESD. As the length of the monitoring patterns 110 increases, the monitoring patterns 110 may be more sensitive to ESD. Also, as the area of the monitoring patterns 110 increases, the monitoring patterns 110 may be more sensitive to ESD. As the monitoring patterns 110 are split in parallel into a larger number of sub-patterns in a widthwise direction, the monitoring patterns 110 may be more sensitive to ESD.

As stated above, when solid dry ice is used as a cleaning agent during a cleaning process, the solid dry ice may apply damage to fine patterns despite its good cleaning capability. Also, when the solid dry ice is sprayed during rotation of the photomask, ESD may be amplified due to the rotation of the photomask and damage to the fine patterns may be unavoidable due to friction with the dry ice.

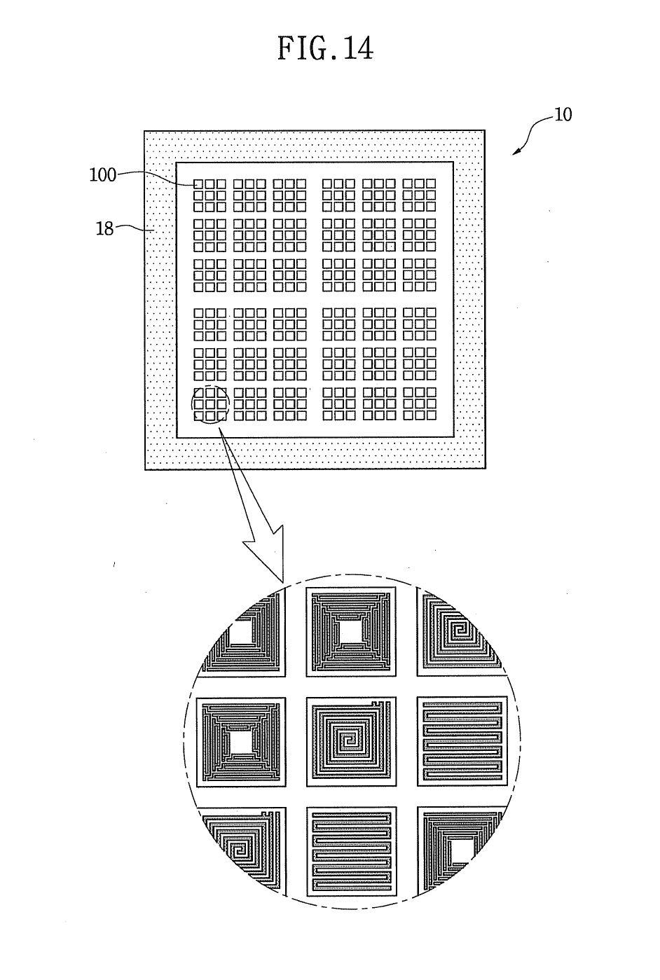

FIG. 14 is a plan view of an all-in-one ESD monitoring photomask capable of monitoring occurrence of pattern failures caused by friction and ESD during a cleaning process according to embodiments of the inventive concept.

Referring to FIG. 14, a variety of assist-bar-type monitoring patterns 110 may be suited to measure the above-described pattern damages. When the monitoring patterns 110 are designed as the type of various ESD-sensitive assist bars, ESD sensitivity and pattern damage caused by a cleaning process may be monitored at the same time.

The width of the assist-bar-type monitoring pattern 110 may be determined within the range of about 150 to 400 nm to monitor pattern damage caused by friction during the spray of dry ice. In this case, ESD and pattern damage caused by a cleaning process may be monitored at the same time using one photomask 10.

Meanwhile, the monitoring patterns 110 may constitute unit monitoring modules 100, which may correspond to a plurality of cells, respectively. The ESD monitoring process may be performed by the unit monitoring module 100 disposed in an edge of the monitoring pattern 110 rather than the unit monitoring module 100 disposed in the center thereof. In this case, the unit monitoring modules 100 may be spaced apart from one another at an interval of about 5 mm or more in order to prevent the unit monitoring modules 100 having respective functions from affecting one another.

In addition, the names and functions of unshown components may be easily understood with reference to other drawings of the present specification and descriptions thereof.

According to the embodiments of the inventive concept as described above, an ESD monitoring module and a photomask including the module may have the following effects.

First, monitoring patterns may be designed in the same direction as or in a vertical direction to an external E-field so that the probability of ESD induced by the external E-field can be maximized.

Second, the ESD sensitivity of monitoring patterns may be extracted by controlling the length, width, and position of the monitoring patterns and a gap between the monitoring patterns so that a process of manufacturing or employing the monitoring patterns can be optimized according to design rules.

Third, pattern failures, such as a cut in patterns or pattern collapse, may be monitored according to the width of monitoring patterns during a cleaning process, so that the process can be optimized according to design rules.

Fourth, various pattern failures may be monitored at the same time using an all-in-one monitoring photomask, thereby increasing monitoring yield.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. An electrostatic discharge (ESD) monitoring module of a photomask, comprising a plurality of monitoring patterns electrically isolated from one another and arranged at right angles to one another.

2. The ESD monitoring module of claim 1, wherein each of the monitoring patterns has a bar shape with a length greater than a width.

3. The ESD monitoring module of claim 1, wherein at least one first monitoring pattern of the plurality of monitoring patterns is arranged in the same direction as an electric field (E-field) existing outside the photomask.

4. The ESD monitoring module of claim 3, wherein at least one second monitoring pattern of the plurality of monitoring patterns is arranged at substantially right angles to the first monitoring pattern in consideration of a direction in which charges move due to rotation of the photomask.

5. The ESD monitoring module of claim 1, wherein when the plurality of monitoring patterns have the same area, the probability of ESD is higher in the monitoring pattern with a smaller width and a greater length than in the monitoring pattern with a greater width and a smaller length.

6. The ESD monitoring module of claim 1, wherein the probability of ESD is higher in the monitoring patterns having a smaller gap therebetween than in the monitoring patterns having a greater gap therebetween.

7. The ESD monitoring module of claim 1, wherein each of the plurality of monitoring patterns is split in parallel into a plurality of sub-patterns in a widthwise direction from the same layout direction.

8. The ESD monitoring module of claim 7, wherein adjacent monitoring patterns disposed in the widthwise direction, out of the plurality of monitoring patterns, are connected to each other by a bridge in the widthwise direction.

9. The ESD monitoring module of claim 1, which is formed in a monitoring-only photomask.

10. The ESD monitoring module of claim 1, which is formed in an additional space of a photomask configured to perform an exposure process.

11. The ESD monitoring module of claim 10, wherein the additional space is a blind area.

12. The ESD monitoring module of claim 1, wherein the monitoring patterns are formed by patterning a light blocking layer formed of chromium (Cr) on a transparent substrate.

13. An electrostatic discharge (ESD) monitoring module of a photomask, comprising first monitoring patterns and second monitoring patterns, which are electrically connected to one another and combine into one line-type pattern,
wherein the line-type pattern is bent such that the first monitoring patterns are designed in the same direction as an electric field (E-field) existing outside the photomask and the second monitoring patterns are designed at right angles to the E-field.

14. The ESD monitoring module of claim 13, wherein the line-type pattern has a spiral structure in which the length of the first or second monitoring patterns is regularly reduced inward.

15. The ESD monitoring module of claim 13, wherein the line-type pattern has a zigzag structure in which the first and second monitoring patterns are repetitively arranged.

16. A monitoring photomask, comprising:
a transparent substrate through which light is transmitted; and
a light blocking pattern through which light is not transmitted, on the transparent substrate,
wherein the light blocking pattern includes a monitoring module on which a plurality of monitoring patterns are arranged, and a blind area adjacent to the monitoring module,
wherein the monitoring patterns have a greater length than a width thereof and are used to monitor both electrostatic discharge (ESD) sensitivity and pattern damage caused by friction when the transparent substrate is rotated during a cleaning process.

17. The monitoring photomask of claim 16, wherein the plurality of monitoring patterns are electrically isolated from one another,
at least one first monitoring pattern of the plurality of monitoring patterns is arranged in the same direction as an electric field (E-field) existing outside the monitoring photomask, and
at least one second monitoring pattern of the plurality of monitoring patterns is arranged at right angles to the E-field.

18. The monitoring photomask of claim 16, wherein each of the monitoring patterns has a simple bar-type structure, and the bar-type structure is arranged at right angles to the blind area so that a potential difference is amplified in a gap between the bar-type monitoring pattern and the blind area or in a gap between adjacent bar-type monitoring patterns.

19. The monitoring photomask of claim 16, wherein the monitoring patterns are electrically connected to one another and combined into one pattern, which is arranged as a spiral type in the same direction as or at right angles to an electric field (E-field) existing outside the monitoring photomask, and
a potential difference is amplified in a gap between the spiral monitoring pattern and the blind area or in a gap between adjacent spiral monitoring patterns.

20. The monitoring photomask of claim 19, wherein the monitoring patterns have a width of about 150 nm to about 400 nm to cause pattern damage due to friction during a cleaning process,
the monitoring patterns constitute unit monitoring modules, which form a plurality of cells, respectively, and
a distance between the unit monitoring modules is about 5 mm or more.
